(19) United States
(12) Patent Application Publication
(10) Pub. No.: US 2026/0074166 A1
(43) Pub. Date: Mar. 12, 2026

(54) ETCHING METHOD, METHOD FOR MANUFACTURING DRAM CAPACITOR, AND PLASMA PROCESSING APPARATUS

(71) Applicant: Tokyo Electron Limited, Tokyo (JP)

(72) Inventor: Koki CHINO, Miyagi (JP)

(73) Assignee: Tokyo Electron Limited, Tokyo (JP)

(21) Appl. No.: 19/390,726

(22) Filed: Nov. 17, 2025

Related U.S. Application Data
(63) Continuation of application No. PCT/JP2024/018950, filed on May 23, 2024.

(30) Foreign Application Priority Data
Jun. 1, 2023 (JP) 2023-090666

(51) Int. Cl. H01J 37/32; H01L 21/311

(52) U.S. Cl. CPC H01J 37/32724; H10P 50/283; H10P 50/73; H01J 37/32091; H01J 2237/334

(57) ABSTRACT

An etching method includes (a) providing a substrate on a substrate support in a chamber, the substrate including a film stack including two or more different silicon-containing films, a single-layer film on the two or more different silicon-containing films, the single-layer film including silicon and nitrogen, and a mask on the single-layer film, the mask having a side wall defining an opening; (b) setting a temperature of the substrate support or the substrate to 10° C. or higher; and (c) etching the single-layer film using a plasma formed from a first processing gas, the first processing gas including a hydrogen fluoride gas.

### CROSS-REFERENCE TO RELATED APPLICATIONS

This application is a bypass continuation application of international application No. PCT/JP2024/018950 having an international filing date of May 23, 2024 and designating the United States, the international application being based upon and claiming the benefit of priority from Japanese Patent Application No. 2023-090666, filed on Jun. 1, 2023, the entire contents of each are incorporated herein by reference.

### BACKGROUND

The exemplary embodiments of the present disclosure relate to an etching method, a method for manufacturing a dynamic random access memory (DRAM) capacitor, and a plasma processing apparatus. For example:

Japanese Patent Application Laid-Open No. 2016-21546 discloses a technique for etching a silicon-containing film.

### SUMMARY

An etching method in one exemplary embodiment of the present disclosure includes (a) providing a substrate on a substrate support in a chamber, the substrate including a film stack including two or more different silicon-containing films, a single-layer film on the two or more different silicon-containing films, the single-layer film including silicon and nitrogen, and a mask on the single-layer film, the mask having a side wall defining an opening; (b) setting a temperature of the substrate support or the substrate to 10° C. or higher; and (c) etching the single-layer film using a plasma formed from a first processing gas, the first processing gas including a hydrogen fluoride gas.

### BRIEF DESCRIPTION OF DRAWINGS

FIG. 1 is a diagram illustrating a configuration example of a plasma processing system.

FIG. 2 is a diagram illustrating a configuration example of a capacitively coupled plasma processing apparatus.

FIG. 3 is a flowchart illustrating an example of an etching method.

FIG. 4 is a diagram illustrating an example of a cross-sectional structure of a substrate W.

FIG. 5 is a flowchart illustrating an example of step ST3.

FIG. 6 is a diagram illustrating an example of the cross-sectional structure of the substrate W in which a silicon nitride film is etched.

FIG. 7 is a diagram illustrating an example of the cross-sectional structure of the substrate W in which a film stack is etched.

### DETAILED DESCRIPTION

Hereinafter, each embodiment of the present disclosure will be described.

In one exemplary embodiment, there is provided an etching method including (a) providing a substrate on a substrate support in a chamber, the substrate including a film stack including two or more different silicon-containing films, a single-layer film including silicon and nitrogen on the film stack, and a mask on the single-layer film, and the mask having a side wall defining at least one opening; (b) setting a temperature of the substrate support or the substrate to 10° C. or higher; and (c) etching the single-layer film using a plasma formed from a first processing gas including a hydrogen fluoride gas.

In one exemplary embodiment, the film stack has at least one stacked structure including a first silicon-containing film and a second silicon-containing film on the first silicon-containing film, the first silicon-containing film contains silicon and nitrogen, and the second silicon-containing film contains silicon and oxygen.

In one exemplary embodiment, the mask includes at least one selected from the group consisting of a silicon-containing film, a metal-containing film, and a carbon-containing film.

In one exemplary embodiment, the mask includes at least one selected from the group consisting of at least one metal selected from the group consisting of tungsten, molybdenum, ruthenium, and titanium, a carbide of the metal, and a silicide of the metal.

In one exemplary embodiment, the mask includes at least one selected from the group consisting of BSi, WSi, and WSiN.

In one exemplary embodiment, a width of the opening is 50 nm or less.

In one exemplary embodiment, the single-layer film is thicker than the first silicon-containing film.

In one exemplary embodiment, the first processing gas further includes at least one carbon-containing gas selected from the group consisting of a fluorocarbon gas and a hydrofluorocarbon gas.

In one exemplary embodiment, a ratio of a flow rate of the hydrogen fluoride gas to a flow rate of the carbon-containing gas is 1 or more and 5 or less.

In one exemplary embodiment, the fluorocarbon gas includes at least one selected from the group consisting of a C₄F₆ gas, a C₄F₈ gas, and a C₃F₈ gas.

In one exemplary embodiment, the hydrofluorocarbon gas includes at least one selected from the group consisting of a CH₂F₂ gas, a CHF₃ gas, a CH₃F gas, a C₃H₂F₄ gas, and a C₄H₂F₆ gas.

In one exemplary embodiment, the first processing gas further includes an oxygen-containing gas.

In one exemplary embodiment, the oxygen-containing gas includes at least one selected from the group consisting of an O₂ gas, a CO gas, and a CO₂ gas.

In one exemplary embodiment, the first processing gas further includes a fluorine-containing gas that does not contain carbon.

In one exemplary embodiment, the fluorine-containing gas includes an NF₃ gas.

In one exemplary embodiment, in the (b), the temperature of the substrate support or the substrate is set in a range of 40° C. or higher and 90° C. or lower.

In one exemplary embodiment, the method further includes (d) etching the film stack using a plasma formed from a second processing gas after the (c).

In one exemplary embodiment, the second processing gas includes a hydrogen fluoride gas and at least one carbon-containing gas selected from the group consisting of a fluorocarbon gas and a hydrofluorocarbon gas.

In one exemplary embodiment, in the (d), the temperature of the substrate support or the substrate when etching the second silicon-containing film included in the film stack is set to be higher than the temperature of the substrate support or the substrate when etching the first silicon-containing film included in the film stack.

In one exemplary embodiment, a method for manufacturing a DRAM capacitor is provided, the method including: (a) providing a substrate on a substrate support in a chamber, the substrate including a film stack including two or more different silicon-containing films, a single-layer film including silicon and nitrogen on the film stack, and a mask on the single-layer film, and the mask having a side wall defining at least one opening; (b) setting a temperature of the substrate support or the substrate to 10° C. or higher; (c) etching the single-layer film using a plasma formed from a first processing gas including a hydrogen fluoride gas; and (d) etching the film stack using a plasma formed from a second processing gas.

In one exemplary embodiment, there is provided a plasma processing apparatus including: a chamber; a substrate support disposed in the chamber; a plasma generator; and a processing circuitry, in which the processing circuitry is configured to execute (a) control of providing a substrate on the substrate support in the chamber, the substrate including a film stack including two or more different silicon-containing films, a single-layer film including silicon and nitrogen on the film stack, and a mask on the single-layer film, and the mask having a side wall defining at least one opening, (b) control of setting a temperature of the substrate support or the substrate to 10° C. or higher, and (c) control of etching the single-layer film using a plasma formed from a first processing gas including a hydrogen fluoride gas.

Hereinafter, each embodiment of the present disclosure will be described in detail with reference to the drawings. In each drawing, the same or similar elements will be given the same reference numerals, and repeated descriptions will be omitted. Unless otherwise specified, a positional relationship such as up, down, left, and right will be described based on a positional relationship illustrated in the drawings. A dimensional ratio in the drawings does not indicate an actual ratio, and the actual ratio is not limited to the ratio illustrated in the drawings.

### Example of Plasma Processing System

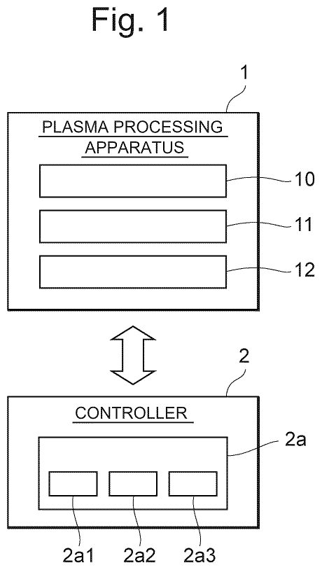

FIG. 1 is a diagram for illustrating a configuration example of a plasma processing system. In an embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. In addition, the plasma processing chamber 10 has at least one gas supply port for supplying at least one processing gas to the plasma processing space and at least one gas exhaust port for exhausting the gas from the plasma processing space. The gas supply port is connected to a gas supply 20 which is described later, and the gas exhaust port is connected to an exhaust system 40 which is described later. The substrate support 11 is disposed in the plasma processing space and has a substrate support surface for supporting a substrate.

The plasma generator 12 is configured to form a plasma from at least one processing gas supplied into the plasma processing space. The plasma formed in the plasma processing space may be a capacitively coupled plasma (CCP), an inductively coupled plasma (ICP), an electron-cyclotron-resonance plasma (ECR plasma), a helicon wave plasma (HWP), a surface wave plasma (SWP), or the like. Further, various types of plasma generators including an alternating current (AC) plasma generator and a direct current (DC) plasma generator may be used. In an embodiment, an AC signal (AC power) used in the AC plasma generator has a frequency in the range of 100 KHz to 10 GHz. Therefore, the AC signal includes a radio frequency (RF) signal and a microwave signal. In an embodiment, the RF signal has a frequency in the range of 100 kHz to 150 MHz.

The controller 2 processes a computer-executable instruction that causes the plasma processing apparatus 1 to execute various steps described in the present disclosure. The controller 2 may be configured to control each element of the plasma processing apparatus 1 to execute the various steps described here. In an embodiment, a part or the entirety of the controller 2 may be included in the plasma processing apparatus 1. The controller 2 may include a processor 2a1, a storage 2a2, and a communication interface 2a3. The controller 2 is realized by, for example, a computer 2a. The processor 2a1 may be configured to read out a program from the storage 2a2 and to execute the read-out program to perform various control operations. This program may be stored in the storage 2a2 in advance, or may be acquired via a medium when necessary. The acquired program is stored in the storage 2a2, is read out from the storage 2a2, and executed by the processor 2a1. The medium may be various storage media readable by the computer 2a or may be a communication line connected to the communication interface 2a3. The processor 2a1 may be a central processing unit (CPU). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors (such as processor 2a1) and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

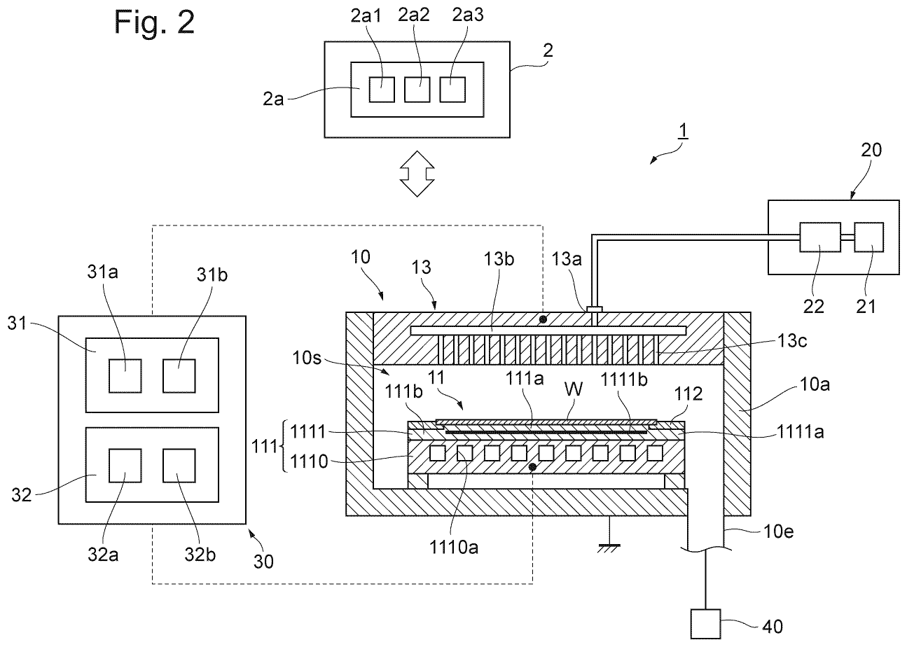

Hereinafter, a configuration example of a capacitively coupled plasma processing apparatus as an example of the plasma processing apparatus 1 will be described. FIG. 2 is a diagram for illustrating a configuration example of the capacitively coupled plasma processing apparatus.

The capacitively coupled plasma processing apparatus 1 includes the plasma processing chamber 10, the gas supply 20, a power supply 30, and the exhaust system 40. In addition, the plasma processing apparatus 1 includes the substrate support 11 and a gas introducer. The gas introducer is configured to introduce at least one processing gas into the plasma processing chamber 10. The gas introducer includes a shower head 13. The substrate support 11 is disposed in the plasma processing chamber 10. The shower head 13 is disposed above the substrate support 11. In an embodiment, the shower head 13 constitutes at least a part of a ceiling of the plasma processing chamber 10. The plasma processing chamber 10 has a plasma processing space 10s defined by the shower head 13, a side wall 10a of the plasma processing chamber 10, and the substrate support 11. The plasma processing chamber 10 is grounded. The shower head 13 and the substrate support 11 are electrically insulated from a housing of the plasma processing chamber 10.

The substrate support 11 includes a main body 111 and a ring assembly 112. The main body 111 has a center region 111a for supporting a substrate W and an annular region 111b for supporting the ring assembly 112. A wafer is an example of the substrate W. The annular region 111b of the main body 111 surrounds the center region 111a of the main body 111 in plan view. The substrate W is disposed on the center region 111a of the main body 111, and the ring assembly 112 is disposed on the annular region 111b of the main body 111 to surround the substrate W on the center region 111a of the main body 111. Therefore, the center region 111a is also referred to as a substrate support surface for supporting the substrate W, and the annular region 111b is also referred to as a ring support surface for supporting the ring assembly 112.

In an embodiment, the main body 111 includes a base 1110 and an electrostatic chuck 1111. The base 1110 includes a conductive member. The conductive member of the base 1110 may function as a lower electrode. The electrostatic chuck 1111 is disposed on the base 1110. The electrostatic chuck 1111 includes a ceramic member 1111a and an electrostatic electrode 1111b disposed in the ceramic member 1111a. The ceramic member 1111a has the center region 111a. In an embodiment, the ceramic member 1111a also has the annular region 111b. Another member that surrounds the electrostatic chuck 1111 may have the annular region 111b, such as an annular electrostatic chuck or an annular insulating member. In this case, the ring assembly 112 may be disposed on the annular electrostatic chuck or the annular insulating member, or may be disposed on both the electrostatic chuck 1111 and the annular insulating member. Further, at least one RF/DC electrode coupled to an RF power supply 31 and/or a DC power supply 32, which will be described later, may be disposed in the ceramic member 1111a. In this case, at least one RF/DC electrode functions as the lower electrode. In a case where a bias RF signal and/or a DC signal, which will be described later, are supplied to at least one RF/DC electrode, the RF/DC electrode is also referred to as a bias electrode. The conductive member of the base 1110 and at least one RF/DC electrode may function as a plurality of lower electrodes. Further, the electrostatic electrode 1111b may function as the lower electrode. Therefore, the substrate support 11 includes at least one lower electrode.

The ring assembly 112 includes one or a plurality of annular members. In an embodiment, one or the plurality of annular members include one or a plurality of edge rings and at least one cover ring. The edge ring is formed of a conductive material or an insulating material, and the cover ring is formed of an insulating material.

In addition, the substrate support 11 may include a temperature-controlled module configured to adjust at least one of the electrostatic chuck 1111, the ring assembly 112, and the substrate to a target temperature. The temperature-controlled module may include a heater, a heat transfer medium, a flow passage 1110a, or a combination thereof. A heat transfer fluid such as brine or a gas flows in the flow passage 1110a. In an embodiment, the flow passage 1110a is formed in the base 1110, and one or a plurality of heaters is disposed in the ceramic member 1111a of the electrostatic chuck 1111. Further, the substrate support 11 may include a heat transfer gas supply configured to supply the heat transfer gas to a gap between a back surface of the substrate W and the center region 111a.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. In addition, the shower head 13 includes at least one upper electrode. In addition to the shower head 13, the gas introducer may include one or a plurality of side gas injectors (SGI) attached to one or a plurality of opening portions formed on the side wall 10a.

The gas supply 20 may include at least one gas source 21 and at least one flow rate controller 22. In an embodiment, the gas supply 20 is configured to supply at least one processing gas to the shower head 13 from each corresponding gas source 21 via each corresponding flow rate controller 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power supply 30 includes the RF power supply 31 coupled to the plasma processing chamber 10 via at least one impedance matching circuit. The RF power supply 31 is configured to supply at least one RF signal (RF power) to at least one lower electrode and/or at least one upper electrode. As a result, the plasma is formed from at least one processing gas supplied to the plasma processing space 10s. Therefore, the RF power supply 31 may function as at least a part of the plasma generator 12. Further, by supplying the bias RF signal to at least one lower electrode, a bias potential is generated in the substrate W, and an ion component in the formed plasma is able to be drawn into the substrate W.

In an embodiment, the RF power supply 31 includes a first RF generator 31a and a second RF generator 31b. The first RF generator 31a is coupled to at least one lower electrode and/or at least one upper electrode via at least one impedance matching circuit and is configured to generate a source RF signal (source RF power) for plasma formation. In an embodiment, the source RF signal has a frequency in the range of 10 MHz to 150 MHz. In an embodiment, the first RF generator 31a may be configured to generate a plurality of source RF signals having different frequencies. The generated one or plurality of source RF signals is supplied to at least one lower electrode and/or at least one upper electrode.

The second RF generator 31b is coupled to at least one lower electrode via at least one impedance matching circuit and is configured to generate the bias RF signal (bias RF power). The frequency of the bias RF signal may be the same as or different from the frequency of the source RF signal. In an embodiment, the bias RF signal has a frequency lower than the frequency of the source RF signal. In an embodiment, the bias RF signal has a frequency in a range of 100 kHz to 60 MHz. In an embodiment, the second RF generator 31b may be configured to generate a plurality of bias RF signals having different frequencies. The generated one or plurality of bias RF signals is supplied to at least one lower electrode. In addition, in various embodiments, at least one of the source RF signal and the bias RF signal may be pulsed.

In addition, the power supply 30 may include a DC power supply 32 coupled to the plasma processing chamber 10. The DC power supply 32 includes a first DC generator 32a and a second DC generator 32b. In an embodiment, the first DC generator 32a is connected to at least one lower electrode, and is configured to generate a first DC signal. The generated first DC signal is applied to at least one lower electrode. In an embodiment, the second DC generator 32b is connected to at least one upper electrode and is configured to generate a second DC signal. The generated second DC signal is applied to at least one upper electrode.

In various embodiments, the first and second DC signals may be pulsed. In this case, a sequence of voltage pulses is applied to at least one lower electrode and/or at least one upper electrode. The voltage pulse may have a pulse waveform having a rectangular shape, a trapezoidal shape, a triangular shape, or a combination thereof. In an embodiment, a waveform generator for generating the sequence of voltage pulses from the DC signal is connected between the first DC generator 32a and at least one lower electrode. Therefore, the first DC generator 32a and the waveform generator configure the voltage pulse generator. In a case where the second DC generator 32b and the waveform generator configure the voltage pulse generator, the voltage pulse generator is connected to at least one upper electrode. The voltage pulse may have a positive polarity or a negative polarity. In addition, the sequence of voltage pulses may include one or a plurality of positively-polarized voltage pulses and one or a plurality of negatively-polarized voltage pulses in one cycle. The first and second DC generators 32a and 32b may be provided in addition to the RF power supply 31, and the first DC generator 32a may be provided instead of the second RF generator 31b.

The exhaust system 40 may be connected to, for example, a gas exhaust port 10e provided at a bottom portion of the plasma processing chamber 10. The exhaust system 40 may include a pressure regulating valve and a vacuum pump. A pressure in the plasma processing space 10s is regulated by the pressure regulating valve. The vacuum pump may include a turbo molecular pump, a dry pump, or a combination thereof.

### Example of Etching Method

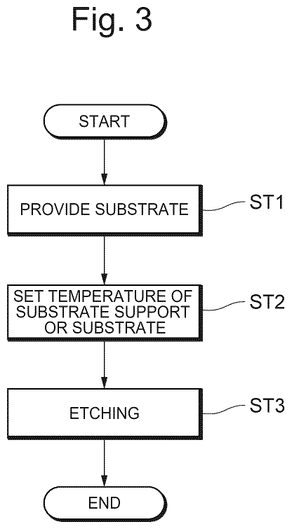

FIG. 3 is a flowchart illustrating an example of an etching method (hereinafter, also referred to as “the present method”) according to one exemplary embodiment. As illustrated in FIG. 3, in an embodiment, the present method includes step ST1 of providing a substrate, step ST2 of setting a temperature of a substrate support or the substrate, and step ST3 of performing etching. In an embodiment, the processing in each step may be executed by the plasma processing apparatus 1 (see FIG. 2). In the following example, the controller 2 controls each unit of the plasma processing apparatus 1 to execute the present method.

### (Step ST1: Provision of Substrate)

In step ST1, the substrate W may be provided in the plasma processing space 10s of the plasma processing apparatus 1. In an embodiment, the substrate W is provided in the center region 111a of the substrate support 11 and is held in the substrate support 11 by the electrostatic chuck 1111.

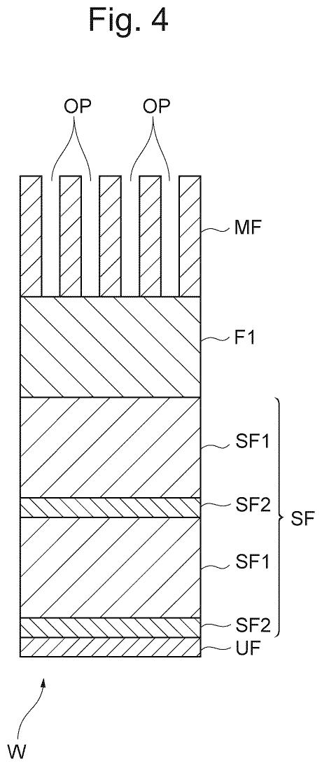

FIG. 4 is a diagram for illustrating an example of a cross-sectional structure of the substrate W provided in step ST1. The substrate W has a film stack SF, a silicon nitride film F₁, and a mask MF. In an embodiment, the film stack SF, the silicon nitride film F₁, and the mask MF are formed on an underlying film UF. In an embodiment, the substrate W may be formed by stacking the underlying film UF, the film stack SF, the silicon nitride film F₁, and the mask MF in this order from below. In an embodiment, the substrate W is used for manufacturing a semiconductor device. The semiconductor device is, for example, a DRAM capacitor.

In an embodiment, the underlying film UF is a silicon wafer, an organic film, a dielectric film, a metal film, a semiconductor film, or the like formed on the silicon wafer. The underlying film UF may be configured by stacking a plurality of films.

In an embodiment, the film stack SF is a film to be etched in the present method. In an embodiment, the film stack SF has two or more different silicon-containing films. The film stack SF includes at least one stacked structure including a first silicon-containing film and a second silicon-containing film. The first silicon-containing film may be a silicon nitride film SF2 containing silicon and nitrogen. The second silicon-containing film may be a silicon oxide film SF1 containing silicon and oxygen. The silicon oxide film SF1 and the silicon nitride film SF2 may contain impurities such as phosphorus, boron, and nitrogen.

In an embodiment, as illustrated in FIG. 4, the film stack SF may be configured by alternately stacking a plurality of silicon oxide films SF1 and a plurality of silicon nitride films SF2. In an embodiment, the film stack SF may be configured by stacking the silicon oxide film SF1 and the silicon nitride film SF2 in a given order. The film stack SF may have the silicon oxide film SF1 on the silicon nitride film SF2 and may have the silicon nitride film F1 on the silicon oxide film SF1. The silicon nitride film SF2 of the film stack SF may be a film thinner than the silicon nitride film F1 on the film stack SF.

In an embodiment, the silicon nitride film F1 is a film to be etched in the present method. The silicon nitride film F1 may be disposed on the film stack SF and may be disposed immediately below the mask MF. The silicon nitride film F1 is an example of a single-layer film containing silicon and nitrogen. The silicon nitride film F1 may include impurities such as phosphorus, boron, and nitrogen. The silicon nitride film F1 may be thicker than the silicon nitride film SF2.

In an embodiment, the mask MF is a film that functions as a mask in the etching of the silicon nitride film F1. The mask MF may be a film different from the film to be etched. The mask MF may be formed from a material having an etching rate to the plasma formed in step ST3, which will be described later, lower than that of the silicon nitride film F1 and the film stack SF. The mask MF may include at least one selected from the group including a silicon-containing film, a metal-containing film, and a carbon-containing film. The mask MF may be a polycrystalline silicon film or a film containing boron and silicon. The mask MF may be, for example, a boron silicide (BSi) film. The mask MF may be a film containing at least one material selected from the group including tungsten, molybdenum, ruthenium, and titanium. The mask MF may contain, for example, a carbide or a silicide of tungsten, molybdenum, or titanium. The mask MF may include tungsten and at least one selected from the group including silicon, carbon, and nitrogen. In an example, the mask MF may include at least one selected from the group including tungsten carbide (WC), tungsten silicide (WSi), WSiN, and WSiC, and may include at least one selected from the group including WSi and WSiN. The mask MF may be an amorphous carbon film. The mask MF may be a single-layer mask of one film or a multilayer mask including two or more film stacks.

As illustrated in FIG. 4, the mask MF may have a side wall that defines at least one opening OP on the silicon nitride film F1. The mask MF may have the opening OP. The opening OP may be a space on the silicon nitride film F1 and may be surrounded by the side wall of the mask MF. That is, the upper surface of the silicon nitride film F1 may have a region covered by the mask MF and a region exposed at a bottom portion of the opening OP.

The opening OP may have any shape in a plan view of the substrate W, that is, in a case where the substrate W is viewed in a direction from top to bottom in FIG. 4. The shape may be, for example, a circle, an ellipse, a rectangle, a line, or a shape in which one or more of these are combined. The mask MF may have a plurality of side walls, and the plurality of side walls may define a plurality of the openings OP. The plurality of openings OP may each have a linear shape and may be arranged at regular intervals to form a line & space pattern. In addition, the plurality of openings OP may each have a hole shape to form an array pattern. A width of the opening OP may be 50 nm or less.

Each of the films (the underlying film UF, the film stack SF, the silicon nitride film F1, and the mask MF) constituting the substrate W may be formed by a CVD method, an ALD method, a spin coating method, or the like, respectively. The opening OP may be formed by etching the mask MF. In addition, the mask MF may be formed by lithography. Each of the above-described films may be a flat film or a film having unevenness. In addition, the substrate W may further have another film under the underlying film UF, and a film stack made of the silicon nitride film F1, the film stack SF, and the underlying film UF may function as the multilayer mask. That is, the film stack of the silicon nitride film F1, the film stack SF, and the underlying film UF may be used as the multilayer mask, and the other film may be etched.

In an embodiment, at least a part of the step of forming each film of the substrate W may be performed in the plasma processing space 10s as a part of step ST1. For example, in a case where the opening OP of the mask MF is formed by etching, the etching of the mask MF in step ST1 and the etching of the silicon nitride film F1 and the film stack SF in step ST3 described later may be continuously executed in the plasma processing space 10s. In an embodiment, after all or a part of each film of the substrate W is formed by an external device or a chamber of the plasma processing apparatus 1, the substrate W may be provided in the plasma processing space 10s.

### (Step ST2: Temperature Setting)

In step ST2, the temperature of the substrate support 11 or the substrate W may be set to a predetermined temperature. In an embodiment, after the substrate W is provided in the center region 111a of the substrate support 11, the temperature of the substrate support 11 or the substrate W is adjusted to a set temperature by the temperature-controlled module. In an embodiment, the temperature of the substrate support 11 or the substrate W is set to 10° C. or higher. In an embodiment, the temperature of the substrate support 11 or the substrate W is set in a range of 40° C. or higher and 90° C. or lower or 40° C. or higher and 80° C. or lower. In an embodiment, the adjustment or maintenance of the temperature of the substrate support 11 or the substrate W includes the adjustment or maintenance of the temperature of the heat transfer fluid flowing through the flow passage 1110a to the set temperature or a temperature different from the set temperature. In an example, the adjustment or maintenance of the temperature of the substrate support 11 or the substrate W includes controlling the pressure of the heat transfer gas (for example, He) between the electrostatic chuck 1111 and the back surface of the substrate W. Timing at which the heat transfer fluid begins to flow in the flow passage 1110a may be before, after, or at the same time as the time at which the substrate W is placed on the substrate support 11. In addition, the temperature of the substrate support 11 or the substrate W may be adjusted before step ST1. That is, the substrate W may be provided on the substrate support 11 after the temperature of the substrate support 11 or the substrate W is adjusted to the set temperature.

### (Step ST3: Etching)

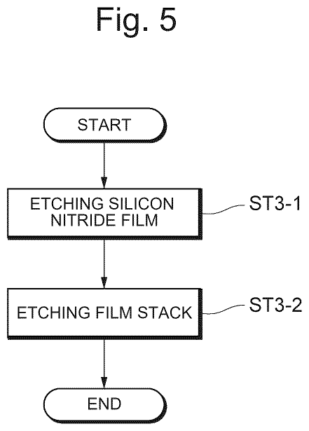

In step ST3, the silicon nitride film F1 and the film stack SF may be etched. FIG. 5 is a flowchart illustrating an example of step ST3. In an embodiment, step ST3 includes step ST3-1 of etching the silicon nitride film F1 using the first processing gas and step ST3-2 of etching the film stack SF using the second processing gas.

In step ST3-1, first, the first processing gas may be supplied into the plasma processing space 10s from the gas supply 20 illustrated in FIG. 2. The first processing gas may include a hydrogen fluoride gas and at least one carbon-containing gas selected from the group including a fluorocarbon gas (CF gas) and a hydrofluorocarbon gas (CHF gas). A ratio of the flow rate of the hydrogen fluoride gas to the flow rate of the carbon-containing gas (the flow rate of the hydrogen fluoride gas/the flow rate of the carbon-containing gas) may be 1 or more and 5 or less, or 2 or more and 4 or less. In an embodiment, the first processing gas may include a hydrogen fluoride gas, a CF gas, a CHF gas, an oxygen-containing gas, and a fluorine-containing gas that does not contain carbon. In an embodiment, the first processing gas may not include a CHF gas, and may include a hydrogen fluoride gas, a CF gas, an oxygen-containing gas, and a fluorine-containing gas that does not contain carbon.

The CF gas may include at least one selected from the group including a C₄F₆ gas, a C₄F₈ gas, and a C₃F₈ gas. As an example, the CF gas may be at least one selected from the group including a C₄F₆ gas, a C₄F₈ gas, a C₃F₈ gas, a CF₄ gas, a C₂F₂ gas, a C₂F₄ gas, a C₃F₆ gas, and a C₅F₈ gas.

The CHF gas may include at least one selected from the group including a CH₂F₂ gas, a CHF₃ gas, a CH₃F gas, a C₃H₂F₄ gas, and a C₄H₂F₆ gas. In an example, the CHF gas may be at least one selected from the group including a CH₂F₂ gas, a CHF₃ gas, a CH₃F gas, a C₃H₂F₄ gas, a C₄H₂F₆ gas, a C₂HF₅ gas, a C₂H₂F₄ gas, a C₂H₃F₃ gas, a C₂H₄F₂ gas, a C₃HF₇ gas, a C₃H₂F₂ gas, a C₃H₂F₆ gas, a C₃H₃F₅ gas, a C₄H₅F₅ gas, a C₄H₂F₈ gas, a C₅H₂F₆ gas, a C₅H₂F₁₀ gas, and a C₅H₃F₇ gas.

The oxygen-containing gas may include at least one selected from the group including an O₂ gas, a CO gas, and a CO₂ gas. In an example, the oxygen-containing gas may be, for example, at least one selected from the group including an O₂ gas, a CO gas, a CO₂ gas, an H₂O gas, and an H₂O₂ gas.

The fluorine-containing gas that does not contain carbon may contain an NF₃ gas.

In step ST3-1, the plasma is formed from the first processing gas, and the silicon nitride film F1 may be etched by using the plasma.

In this case, in an embodiment, the source RF signal is supplied to the lower electrode of the substrate support 11 and/or the upper electrode of the shower head 13 illustrated in FIG. 2. As a result, an RF electric field is generated between the shower head 13 and the substrate support 11, and the plasma is formed from the processing gas in the plasma processing space 10s. In this case, a bias signal may be supplied to the lower electrode of the substrate support 11. In this case, a bias potential is generated between the plasma and the substrate W. Active species such as ions and radicals in the plasma are attracted to the substrate W, and the silicon nitride film F1 is etched by the active species. The bias signal may be the bias RF signal supplied from the RF power supply 31 or the bias DC signal supplied from the DC power supply 32.

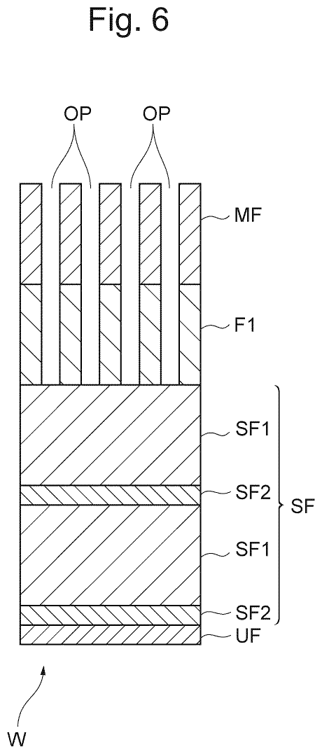

FIG. 6 is a diagram for illustrating an example of the cross-sectional structure of the substrate W in which the silicon nitride film F1 is etched in step ST3-1. In an embodiment, in the silicon nitride film F1, a portion (a portion exposed in the opening OP) that is not covered by the mask MF is etched to form a recess portion.

Next, in step ST3-2 illustrated in FIG. 5, the plasma is formed from the second processing gas, and the film stack SF may be etched using the plasma.

In step ST3-2, first, the second processing gas may be supplied into the plasma processing space 10s from the gas supply 20 illustrated in FIG. 2. The second processing gas may include a hydrogen fluoride gas and at least one carbon-containing gas selected from the group including a CF gas and a CHF gas. The second processing gas may not include a hydrogen fluoride gas. In an embodiment, the second processing gas may include a CF gas, an oxygen-containing gas, and a fluorine-containing gas that does not contain carbon. In an embodiment, the second processing gas may further include a CHF gas. The second processing gas may be the same as the first processing gas.

The CF gas may include at least one selected from the group including a C₄F₆ gas, a C₄F₈ gas, and a C₃F₈ gas. As an example, the CF gas may be at least one selected from the group including a C₄F₆ gas, a C₄F₈ gas, a C₃F₈ gas, a CF₄ gas, a C₂F₂ gas, a C₂F₄ gas, a C₃F₆ gas, and a C₅F₈ gas.

The CHF gas may include at least one selected from the group including a CH₂F₂ gas, a CHF₃ gas, a CH₃F gas, a C₃H₂F₄ gas, and a C₄H₂F₆ gas. In an example, the CHF gas may be at least one selected from the group including a CH₂F₂ gas, a CHF₃ gas, a CH₃F gas, a C₃H₂F₄ gas, a C₄H₂F₆ gas, a C₂HF₈ gas, a C₂H₂F₄ gas, a C₂H₃F₃ gas, a C₂H₄F₂ gas, a C₃HF₇ gas, a C₃H₂F₂ gas, a C₃H₂F₆ gas, a C₃H₃F₅ gas, a C₄H₅F₅ gas, a C₄H₂F₈ gas, a C₆H₂F₆ gas, a C₆H₂F₁₀ gas, and a C₅H₃F₇ gas.

The oxygen-containing gas may include at least one selected from the group including an O₂ gas, a CO gas, and a CO₂ gas. In an example, the oxygen-containing gas may be, for example, at least one gas selected from the group including O₂, CO, CO₂, H₂O, and H₂O₂.

The fluorine-containing gas that does not contain carbon may contain an NF₃ gas.

In step ST3-2, the plasma is formed from the second processing gas, and the film stack SF may be etched using the plasma.

At this time, similarly to step ST3-1, the source RF signal is supplied to the lower electrode of the substrate support 11 and/or the upper electrode of the shower head 13 illustrated in FIG. 2, and the plasma is formed from the second processing gas in the plasma processing space 10s. In this case, a bias signal may be supplied to the lower electrode of the substrate support 11. The bias signal may be the bias RF signal supplied from the RF power supply 31 or the bias DC signal supplied from the DC power supply 32. The silicon oxide film SF1 and the silicon nitride film SF2 of the film stack SF are alternately etched by the formed plasma.

When etching the silicon oxide film SF1 and when etching the silicon nitride film SF2, the gas species constituting the second processing gas may be the same or different. In a case where the gas species of the second processing gas is different, when etching the silicon oxide film SF1, the second processing gas may include a CF gas, an oxygen-containing gas, and a fluorine-containing gas that does not contain carbon. When etching the silicon nitride film SF2, a CF gas, a CHF gas, an oxygen-containing gas, and a fluorine-containing gas that does not contain carbon may be provided.

In step ST3-2, the temperature of the substrate support 11 or the substrate W when etching the silicon oxide film SF1 may be set to be higher than the temperature of the substrate support 11 or the substrate W when etching the silicon nitride film SF2.

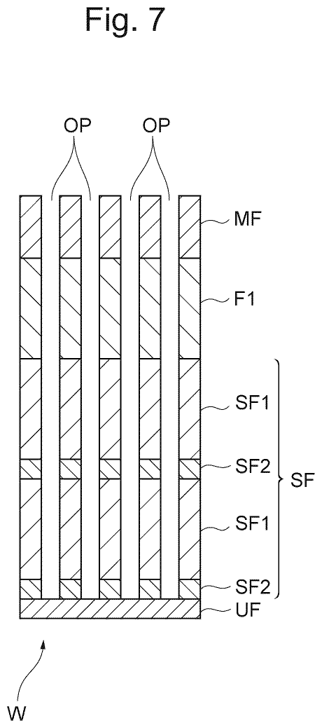

FIG. 7 is a diagram for illustrating an example of the cross-sectional structure of the substrate W in which the film stack SF is etched in step ST3-2. In an embodiment, in the film stack SF, the portion (the portion exposed in the opening OP) that is not covered by the mask MF is etched to form the recess portion.

According to the present exemplary embodiment, the etching method includes (a) a step of providing the substrate W including the silicon nitride film F1 and the mask MF on the silicon nitride film F1 on the substrate support 11 disposed in the chamber 10, (b) a step of setting the temperature of the substrate support 11 or the substrate W to 10° C. or higher, and (c) a step of etching the silicon nitride film F1 using the plasma formed from the first processing gas including hydrogen fluoride gas and at least one carbon-containing gas selected from the group including CF gas and CHF gas. Since the first processing gas includes the hydrogen fluoride gas, the etching selectivity of the silicon nitride film F1 with respect to the mask MF is able to be improved. In addition, since the first processing gas includes the carbon-containing gas, the wall surface of the hole of the silicon nitride film F1 is protected, and bowing in which the diameter of a part of the hole increases is able to be suppressed.

### Examples

An experiment was performed in which a substrate having a mask on a silicon nitride film was subjected to etching processing with a predetermined processing gas. The temperature of the substrate support was set to 10° C. or higher. The experiment was performed using the following processing gases of (1) to (3).
(1) Processing gas including CH₂F₂ gas (flow rate ratio CH₂F₂ gas:C₄F₆ gas:HF=4.5:1:0)
(2) Processing gas including CH₂F₂ gas, C₄F₆ gas, and hydrogen fluoride gas (flow rate ratio CH₂F₂ gas:C₄F₆ gas:HF=1:1:4)
(3) Processing gas including C₄F₆ gas and hydrogen fluoride gas (flow rate ratio CH₂F₂ gas:C₄F₆ gas:HF=0:1:2.5)

In a case where the processing gases of (2) and (3) were used, the etching rate of the mask was decreased as compared with a case where the processing gas of (1) was used. The bowing of the hole in the silicon nitride film was reduced. In a case where the processing gas of (3) was used, the etching rate of the mask was decreased and the etching rate of the silicon nitride film was increased, as compared with a case where the processing gas of (2) was used. The bowing of the hole in the silicon nitride film was reduced. From such an experiment, it was confirmed that the etching selectivity of the silicon nitride film with respect to the mask is improved and the bowing of the hole of the silicon nitride film is reduced by including the hydrogen fluoride gas and at least one carbon-containing gas selected from the group including a CF gas and a CHF gas in the processing gas.

In the above-described embodiment, the present method is not limited to the inductively coupled plasma processing apparatus, and may be performed by another type of the plasma processing apparatus, for example, a plasma processing apparatus that forms a capacitively coupled plasma, a plasma processing apparatus that forms an ECR plasma, a plasma processing apparatus that forms a helicon wave plasma, or a plasma processing apparatus that forms a surface wave plasma.

The embodiments of the present disclosure further include the following aspects.

### ADDENDUM 1

### An Etching Method Including:

(a) providing a substrate on a substrate support in a chamber, the substrate including a film stack including two or more different silicon-containing films, a single-layer film including silicon and nitrogen on the film stack, and a mask on the single-layer film, and the mask having a side wall defining at least one opening;
(b) setting a temperature of the substrate support or the substrate to 10° C. or higher; and
(c) etching the single-layer film using a plasma formed from a first processing gas including a hydrogen fluoride gas.

### ADDENDUM 2

The etching method according to Addendum 1, in which the film stack has at least one stacked structure including a first silicon-containing film and a second silicon-containing film on the first silicon-containing film, the first silicon-containing film contains silicon and nitrogen, and the second silicon-containing film contains silicon and oxygen.

### ADDENDUM 3

The etching method according to Addendum 1, in which the mask includes at least one selected from the group consisting of a silicon-containing film, a metal-containing film, and a carbon-containing film.

### ADDENDUM 4

The etching method according to Addendum 1, in which the mask includes at least one selected from the group consisting of at least one metal selected from the group consisting of tungsten, molybdenum, ruthenium, and titanium, a carbide of the metal, and a silicide of the metal.

### ADDENDUM 5

The etching method according to Addendum 1, in which the mask includes at least one selected from the group consisting of BSi, WSi, and WSiN.

### ADDENDUM 6

The etching method according to any one of Addenda 1 to 5, in which a width of the opening is 50 nm or less.

### ADDENDUM 7

The etching method according to Addendum 2, in which the single-layer film is thicker than the first silicon-containing film.

### ADDENDUM 8

The etching method according to any one of Addenda 1 to 7, in which the first processing gas further includes at least one carbon-containing gas selected from the group consisting of a fluorocarbon gas and a hydrofluorocarbon gas.

### ADDENDUM 9

The etching method according to Addendum 8, in which a ratio of a flow rate of the hydrogen fluoride gas to a flow rate of the carbon-containing gas is 1 or more and 5 or less.

### ADDENDUM 10

The etching method according to Addendum 8 or 9, in which the fluorocarbon gas includes at least one selected from the group consisting of a C₄F₆ gas, a C₄F₈ gas, and a C₃F₈ gas.

### ADDENDUM 11

The etching method according to any one of Addenda 8 to 10, in which the hydrofluorocarbon gas includes at least one selected from the group consisting of a CH₂F₂ gas, a CHF₃ gas, a CH₃F gas, a C₃H₂F₄ gas, and a C₄H₂F₆ gas.

### ADDENDUM 12

The etching method according to any one of Addenda 8 to 11, in which the first processing gas further includes an oxygen-containing gas.

### ADDENDUM 13

The etching method according to Addendum 12, in which the oxygen-containing gas includes at least one selected from the group consisting of an O₂ gas, a CO gas, and a CO₂ gas.

### ADDENDUM 14

The etching method according to any one of Addenda 8 to 13, in which the first processing gas further includes a fluorine-containing gas that does not contain carbon.

### ADDENDUM 15

The etching method according to Addendum 14, in which the fluorine-containing gas includes an NF₃ gas.

### ADDENDUM 16

The etching method according to any one of Addenda 1 to 15, in which in the (b), the temperature of the substrate support or the substrate is set in a range of 40° C. or higher and 90° C. or lower.

### ADDENDUM 17

The etching method according to any one of Addenda 1 to 16, further including: (d) etching the film stack using a plasma formed from a second processing gas after the (c).

### ADDENDUM 18

The etching method according to Addendum 17, in which the second processing gas includes a hydrogen fluoride gas and at least one carbon-containing gas selected from the group consisting of a fluorocarbon gas and a hydrofluorocarbon gas.

### ADDENDUM 19

The etching method according to Addendum 17 or 18, in which
the film stack has at least one stacked structure including a first silicon-containing film and a second silicon-containing film on the first silicon-containing film, the first silicon-containing film contains silicon and nitrogen,
the second silicon-containing film contains silicon and oxygen, and
in the (d), the temperature of the substrate support or the substrate when etching the second silicon-containing film included in the film stack is set to be higher than the temperature of the substrate support or the substrate when etching the first silicon-containing film included in the film stack.

### ADDENDUM 20

A method for manufacturing a dynamic random access memory (DRAM) capacitor, including:
(a) providing a substrate on a substrate support in a chamber, the substrate including a film stack including two or more different silicon-containing films, a single-layer film including silicon and nitrogen on the film stack, and a mask on the single-layer film, and the mask having a side wall defining at least one opening;
(b) setting a temperature of the substrate support or the substrate to 10° C. or higher;
(c) etching the single-layer film using a plasma formed from a first processing gas including a hydrogen fluoride gas; and
(d) etching the film stack using a plasma formed from a second processing gas.

### ADDENDUM 21

### a Plasma Processing Apparatus Including:

a chamber;
a substrate support disposed in the chamber;
a plasma generator; and
a processing circuitry, in which
the processing circuitry is configured to execute
(a) control of providing a substrate on the substrate support in the chamber, the substrate including a film stack including two or more different silicon-containing films, a single-layer film including silicon and nitrogen on the film stack, and a mask on the single-layer film, and the mask having a side wall defining at least one opening,
(b) control of setting a temperature of the substrate support or the substrate to 10° C. or higher, and
(c) control of etching the single-layer film using a plasma formed from a first processing gas including a hydrogen fluoride gas.

Each of the above embodiments is described for the purpose of description, and it is not intended to limit the scope of the present disclosure. Each of the above embodiments may be modified in various ways without departing from the scope and gist of the present disclosure. For example, some configuration elements in one embodiment are able to be added to another embodiment. In addition, some configuration elements in one embodiment are able to be replaced with corresponding configuration elements in another embodiment.

According to one exemplary embodiment of the present disclosure, it is possible to provide a technique for improving the etching selectivity of the silicon nitride film with respect to the mask.

What is claimed is:

1. An etching method, comprising:
(a) providing a substrate on a substrate support in a chamber, the substrate including a film stack including:
two or more different silicon-containing films,
a single-layer film on the two or more different silicon-containing films, the single-layer film including silicon and nitrogen, and
a mask on the single-layer film, the mask having a side wall defining an opening;
(b) setting a temperature of the substrate support or the substrate to 10° C. or higher; and
(c) etching the single-layer film using a plasma formed from a first processing gas, the first processing gas including a hydrogen fluoride gas.

2. The etching method according to claim 1, wherein
the film stack includes at least one stacked structure the two or more different silicon-containing films,
the two or more silicon-containing films include a first silicon-containing film and a second silicon-containing film on the first silicon-containing film,
the first silicon-containing film contains silicon and nitrogen, and
the second silicon-containing film contains silicon and oxygen.

3. The etching method according to claim 1, wherein the mask includes at least one selected from a group including a silicon-containing film, a metal-containing film, and a carbon-containing film.

4. The etching method according to claim 1, wherein the mask includes at least one selected from a group including tungsten, molybdenum, ruthenium, and titanium, a carbide of the metal, and a silicide of the metal.

5. The etching method according to claim 1, wherein the mask includes at least one selected from a group including BSi, WSi, and WSiN.

6. The etching method according to claim 1, wherein a width of the opening is 50 nm or less.

7. The etching method according to claim 2, wherein the single-layer film is thicker than the first silicon-containing film.

8. The etching method according to claim 1, wherein the first processing gas further includes at least one carbon-containing gas selected from a group including a fluorocarbon gas and a hydrofluorocarbon gas.

9. The etching method according to claim 8, wherein a ratio of a flow rate of the hydrogen fluoride gas to a flow rate of the carbon-containing gas is 1 or more and 5 or less.

10. The etching method according to claim 8, wherein the fluorocarbon gas includes at least one selected from a group including a C₄F₆ gas, a C₄F₈ gas, and a C₃F₈ gas.

11. The etching method according to claim 8, wherein the hydrofluorocarbon gas includes at least one selected from a group including a CH₂F₂ gas, a CHF₃ gas, a CH₃F gas, a C₃H₂F₄ gas, and a C₄H₂F₆ gas.

12. The etching method according to claim 8, wherein the first processing gas further includes an oxygen-containing gas.

13. The etching method according to claim 12, wherein the oxygen-containing gas includes at least one selected from a group including an O₂ gas, a CO gas, and a CO₂ gas.

14. The etching method according to claim 8, wherein the first processing gas further includes a fluorine-containing gas that does not contain carbon.

15. The etching method according to claim 14, wherein the fluorine-containing gas includes an NF₃ gas.

16. The etching method according to claim 1, wherein in the (b), the temperature of the substrate support or the substrate is set in a range of 40° C. or higher and 90° C. or lower.

17. The etching method according to claim 2, further comprising:
(d) etching the film stack using a plasma formed from a second processing gas after the (c).

18. The etching method according to claim 17, wherein the second processing gas includes a hydrogen fluoride gas and at least one carbon-containing gas selected from a group including a fluorocarbon gas and a hydrofluorocarbon gas.

19. The etching method according to claim 17, wherein, in the (d), the temperature of the substrate support or the substrate when etching the second silicon-containing film included in the film stack is set to be higher than the temperature of the substrate support or the substrate when etching the first silicon-containing film included in the film stack.

20. A method for manufacturing a dynamic random access memory capacitor, the method comprising:
(a) providing a substrate on a substrate support in a chamber, the substrate including a film stack including:
two or more different silicon-containing films,
a single-layer film on the two or more different silicon-containing films, the single-layer film including silicon and nitrogen, and
a mask on the single-layer film, the mask having a side wall defining an opening;
(b) setting a temperature of the substrate support or the substrate to 10° C. or higher;
(c) etching the single-layer film using a plasma formed from a first processing gas, the first processing gas including a hydrogen fluoride gas; and
(d) etching the film stack using a plasma formed from a second processing gas.

21. A plasma processing apparatus, comprising:
a chamber;
a substrate support disposed in the chamber;
a plasma generator; and
processing circuitry configured to:
(a) control providing a substrate on the substrate support in the chamber, the substrate including a film stack including:
two or more different silicon-containing films,
a single-layer film on the two or more different silicon-containing films, the single-layer film including silicon and nitrogen, and
a mask on the single-layer film, the mask having a side wall defining at least one opening;
(b) control setting a temperature of the substrate support or the substrate to 10° C. or higher, and
(c) control etching the single-layer film using a plasma formed by the plasma generator from a first processing gas, the first processing gas including a hydrogen fluoride gas.
